(19) United States
(12) Patent Application Publication
(10) Pub. No.: US 2025/0031353 A1
(43) Pub. Date: Jan. 23, 2025

(54) DISPLAY MODULE AND DISPLAY APPARATUS

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventors: Ge SUN, Beijing (CN); Yong YU, Beijing (CN); Xiaoxia HUANG, Beijing (CN)

(73) Assignees: CHENGDU BOE OPTOELECTRONICS TECHNOLOGY CO., LTD., Sichuan (CN); BOE TECHNOLOGY GROUP CO., LTD., Beijing (CN)

(21) Appl. No.: 18/548,507

(22) PCT Filed: Feb. 22, 2023
(86) PCT No.: PCT/CN2023/077523

§ 371 Date: Aug. 31, 2023

(30) Foreign Application Priority Data
Apr. 26, 2022 (CN) 202210447015.7

(51) Int. Cl. H05K 7/20

(52) U.S. Cl. CPC H05K 7/20963

(57) ABSTRACT

A display module and a display apparatus. The display module includes a display panel, a circuit board, an electronic device, a copper foil and a graphite film. The circuit board is electrically connected to the display panel. The circuit board includes a first surface and a second surface that are opposite to each other. The electronic device is disposed on the first surface of the circuit board. The copper foil covers the electronic device. The graphite film is disposed on the second surface of the circuit board.

### CROSS-REFERENCE TO RELATED APPLICATIONS

This application is a national phase entry under 35 USC 371 of International Patent Application No. PCT/CN2023/077523, filed on Feb. 22, 2023, which claims priority to Chinese Patent Application No. 202210447015.7, filed on Apr. 26, 2022, which are incorporated herein by reference in their entirety.

### TECHNICAL FIELD

The present disclosure relates to the field of display technologies, and in particular, to a display module and a display apparatus.

### BACKGROUND

With the continuous development of display technologies, the thermal stability and reliability of display apparatuses has become one of the more important performances. Circuit boards, as core components of electronic products, carry chips, resistors, capacitors, inductors and other components whose power is gradually increased with the development of large-sized display apparatuses, so that the heat flux of the circuit boards increases sharply. Correspondingly, the thermal stability and reliability of the display apparatuses is poor.

### SUMMARY

In an aspect, a display module is provided, which includes a display panel, a circuit board, an electronic device, a copper foil and a graphite film.

The circuit board is electrically connected to the display panel. The circuit board includes a first surface and a second surface that are opposite to each other. The electronic device is disposed on the first surface of the circuit board. The copper foil covers the electronic device. The graphite film is disposed on the second surface of the circuit board.

In some embodiments, the display module further includes a first bonding layer. The first bonding layer is disposed between the circuit board and the graphite film, and the first bonding layer is provided therein with a plurality of openings.

In some embodiments, the circuit board further includes first exposed copper regions located on the second surface, and the first bonding layer is arranged to bypass the first exposed copper regions.

In some embodiments, the graphite film is arranged to bypass the first exposed copper regions.

In some embodiments, a thickness of the first bonding layer is approximately in a range of 0.001 mm to 0.003 mm.

In some embodiments, a diameter of at least one opening in the first bonding layer is approximately in a range of 0.3 mm to 0.7 mm.

In some embodiments, a distance between two adjacent openings among the plurality of openings is approximately in a range of 8 mm to 12 mm.

In some embodiments, the display module further includes a second bonding layer. The second bonding layer includes a plurality of first bonding blocks, and the plurality of first bonding blocks are located on a side of the graphite film away from the circuit board.

In some embodiments, the plurality of first bonding blocks are arranged to bypass the electronic device.

In some embodiments, the circuit board further includes first exposed copper regions located on the second surface. The second bonding layer further includes a second bonding block covering a first exposed copper region, and the second bonding block is conductive and in electrical contact with the first exposed copper region.

In some embodiments, the display module further includes a middle frame. The middle frame is bonded to the second bonding layer. In a case where the second bonding layer includes a second bonding block, the middle frame is electrically connected to the second bonding block.

In some embodiments, a thickness of the first bonding blocks is approximately in a range of 0.005 mm to 0.015 mm.

In some embodiments, the display module further includes a third bonding layer. The third bonding layer is disposed between the electronic device and the copper foil. The third bonding layer covers the electronic device.

In some embodiments, the circuit board further includes second exposed copper regions located on the first surface, and the third bonding layer is arranged to bypass the second exposed copper regions.

In some embodiments, the third bonding layer includes through holes for bypassing the second exposed copper regions, and the copper foil is in electrical contact with the second exposed copper regions through the through holes.

In some embodiments, a thickness of the third bonding layer is approximately in a range of 0.005 mm to 0.01 mm.

In some embodiments, the display module further includes: a first bonding layer disposed between the circuit board and the graphite film, a second bonding layer disposed on a side of the graphite film away from the circuit board, and a third bonding layer disposed between the electronic device and the copper foil. A material of at least one of the first bonding layer, the second bonding layer and the third bonding layer includes an acrylic material.

In some embodiments, a thickness of the graphite film is approximately in a range of 0.02 mm to 0.035 mm.

In some embodiments, a thickness of the copper foil is approximately in a range of 0.015 mm to 0.02 mm.

In another aspect, a display apparatus is provided, which includes the display module as described in any one of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a top view of a display apparatus, in accordance with some embodiments;

FIG. 2 is a structural diagram of a display module, in accordance with some embodiments;

FIG. 3 is a structural diagram of another display module, in accordance with some embodiments;

FIG. 4 is a top view of a first surface of a circuit board, in accordance with some embodiments;

FIG. 5 is a top view of a first surface of a circuit board, in accordance with some other embodiments;

FIG. 6 is a top view of a second surface of a circuit board, in accordance with some embodiments;

FIG. 7 is a top view of a second surface of a circuit board, in accordance with some other embodiments;

FIG. 8 is a structural diagram of a first bonding layer, in accordance with some embodiments;

FIG. 9 is a structural diagram of a second bonding layer, in accordance with some embodiments;

FIG. 10 is a top view of a second surface of a circuit board, in accordance with yet some other embodiments;

FIG. 11 is a section view taken along the line A-A′ in FIG. 10; and

FIG. 12 is a temperature detection diagram of a display apparatus, in accordance with some embodiments.

### DETAILED DESCRIPTION

The technical solutions in some embodiments of the present disclosure will be described clearly and completely with reference to the accompanying drawings. However, the described embodiments are merely some but not all of the embodiments of the present disclosure. All other embodiments obtained by a person of ordinary skilled in the art on a basis of the embodiments of the present disclosure shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, specific features, structures, materials, or characteristics described herein may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, features defined with “first” and “second” may explicitly or implicitly include one or more of the features. In the description of the embodiments of the present disclosure, the term “a plurality of” or “the plurality of” means two or more unless otherwise specified.

In the description of some embodiments, the expressions “electrically connected” and “connected” and derivatives thereof may be used. For example, the term “electrically connected” may be used in the description of some embodiments to indicate that two or more components are in direct physical contact or electrical contact with each other. The embodiments disclosed herein are not necessarily limited to the content herein.

The phrase “at least one of A, B and C” has the same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The term such as “about”, “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

In the description of the present disclosure, it will be understood that, orientations or positional relationships indicated by the terms such as “center”, “longitudinal”, “transverse”, “length”, “width”, “vertical”, “horizontal”, “inner”, “outer” and the like are based on orientations or positional relationships shown in the drawings, which are merely for convenience in description of the present disclosure and simplifying the description, but are not to indicate or imply that the indicated devices or elements must have a particular orientation, or must be constructed or operated in a particular orientation.

It will be understood that, when a layer or element is referred to as being on another layer or substrate, it may be that the layer or element is directly on the another layer or substrate, or it may be that intermediate layer(s) exist between the layer or element and the another layer or substrate.

Exemplary embodiments are described herein with reference to sectional views and/or plan views as idealized exemplary drawings. In the drawings, thicknesses of layers and sizes of regions are enlarged for clarity. Variations in shapes relative to the accompanying drawings due to, for example, manufacturing technologies and/or tolerances may be envisaged. Therefore, the exemplary embodiments should not be construed to be limited to the shapes of regions shown herein, but to include deviations in the shapes due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

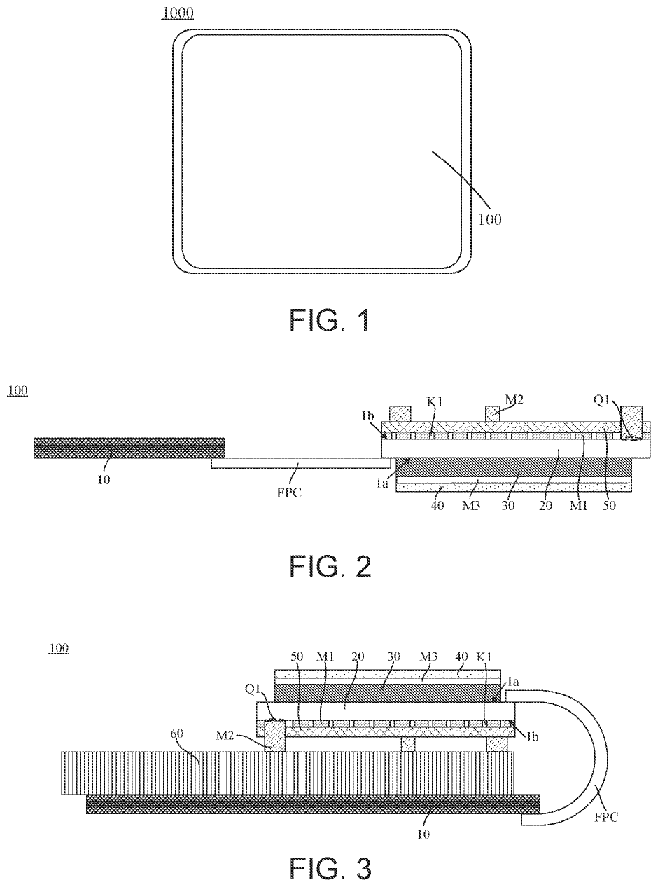

FIG. 1 is a top view of a display apparatus 1000 provided in some embodiments of the present disclosure. The display apparatus 1000 may be any device that displays an image whether in motion (e.g., a video) or stationary (e.g., a still image), and whether textual or graphical. More specifically, it is anticipated that the described embodiments may be implemented in or associated with a variety of electronic devices, such as (but not limited to), mobile phones, wireless devices, personal digital assistants (PDAs), virtual reality (VR) displays, hand-held or portable computers, global positioning system (GPS) receivers/navigators, cameras, MP4 video players, video cameras, game consoles, watches, clocks, calculators, television monitors, computer monitors, automobile displays (e.g., odometer displays), navigators, cockpit controllers and/or displays, camera view displays (such as rear view camera displays in vehicles), electronic photos, electronic billboards or indicators, projectors, building structures, packagings and aesthetic structures (such as a display for an image of a piece of jewelry), etc.

As shown in FIG. 1, the display apparatus 1000 may include a display module 100.

For example, the display apparatus 1000 may further include a front frame and a rear housing. The front frame is disposed on a display side of the display module 100 and surrounds the display module 100. The back housing is disposed on a non-display side (a side opposite to the display side) of the display module 100. The back housing and the front frame are assembled to realize the protection and fixing of the display module 100.

In the related art, a display module includes a display panel and a circuit board. The display panel is configured to display images. The circuit board is electrically connected to the display panel, and the circuit board is configured to carry components. The components carried by the circuit board provide power signals, light-emitting driving signals, and control signals, so as to drive the display panel to display images.

With the gradual development of the large-sized display apparatus, the size of the display panel increases, and accordingly the number of light-emitting devices in the display panel increases. Therefore, the driving current required for the light-emitting of the display panel increases, the power consumption and the number of driver chips, resistors, capacitors and other components carried by the circuit board which is used to provide the driving current to the display panel also increase accordingly. As a result, the heat flux of the circuit board increases seriously, the temperature of the circuit board increases, and the performance and life of the components are affected.

In addition, when the circuit board is assembled on the non-display side of the display panel, the heat of the circuit board will be quickly transferred to the display panel, which causes devices with poor heat resistance in the display panel, such as light-emitting devices, to be greatly damaged, so that the display effect of the display panel is affected, and the overall life of the display apparatus is shortened.

In order to solve the above problems, some embodiments of the present disclosure provide the display module 100.

As shown in FIGS. 2 and 3, the display module 100 includes a display panel 10, a circuit board 20, an electronic device 30, a copper foil 40 and a graphite film 50.

The display panel 10 may be a liquid crystal display panel (LCD); or the display panel 10 may be an electroluminescence display panel or a photoluminescence display panel. In a case where the display panel 10 is an electroluminescent display panel, the electroluminescent display panel may be an organic light-emitting diode (OLED) display panel or a quantum dot light-emitting diode (QLED) display panel. In a case where the display panel 10 is a photoluminescent display panel, the photoluminescent display panel may be a quantum dot photoluminescent display panel.

As shown in FIGS. 2 and 3, the circuit board 20 includes a first surface 1a and a second surface 1b that are opposite to each other.

The second surface 1b is configured to carry components. For example, the components are soldered onto the second surface 1b.

For example, the first surface 1a may also be configured to carry components. That is, the first surface 1a and the second surface 1b of the circuit board 20 may both carry components, which is not limited in the embodiments of the present disclosure.

The components carried by the circuit board 20 are configured to transmit light-emitting driving signals, power signals, control signals, etc. to the display panel 10, so as to drive and control the display panel 10 to emit light and display images.

It should be noted that the “circuit board 20” mentioned in the embodiments of the present disclosure is a circuit board where the components have not yet been soldered.

As shown in FIGS. 2 and 3, the circuit board 20 is electrically connected to the display panel 10.

For example, the display module 100 may further include a plurality of circuit boards 20, and the plurality of circuit boards 20 are electrically connected to the display panel 10.

For example, as shown in FIGS. 2 and 3, the circuit board 20 and the display panel 10 may be electrically connected through a flexible connection board, and the flexible connection board may be a flexible printed circuit (FPC) or a chip-on-film (COF). For example, the circuit board 20 and the display panel 10 are bonded to and electrically connected to the FPC.

For example, as shown in FIG. 3, the FPC is bent toward the non-display side of the display panel 10, so that the circuit board 20 is located on the non-display side of the display panel 10. The display panel 10 and the circuit board 20 located on the non-display side of the display panel 10 are assembled to form the display module.

It should be noted that the display side of the display panel 10 refers to a side of the display panel 10 that performs display, and the non-display side refers to the side opposite to the display side.

As shown in FIGS. 2 and 3, the electronic device E is disposed on the first surface 1a of the circuit board 20.

For example, the electronic device 30 may include a logic circuit (a timing controller integrated circuit (Tcon IC)), a power management integrated circuit (PMIC), metal oxide semiconductor (MOS) transistors, a light-emitting device driving circuit, and various capacitors, resistors, and inductors. The electronic device 30 has heavy loads and is one of the main heating components in the display module 100.

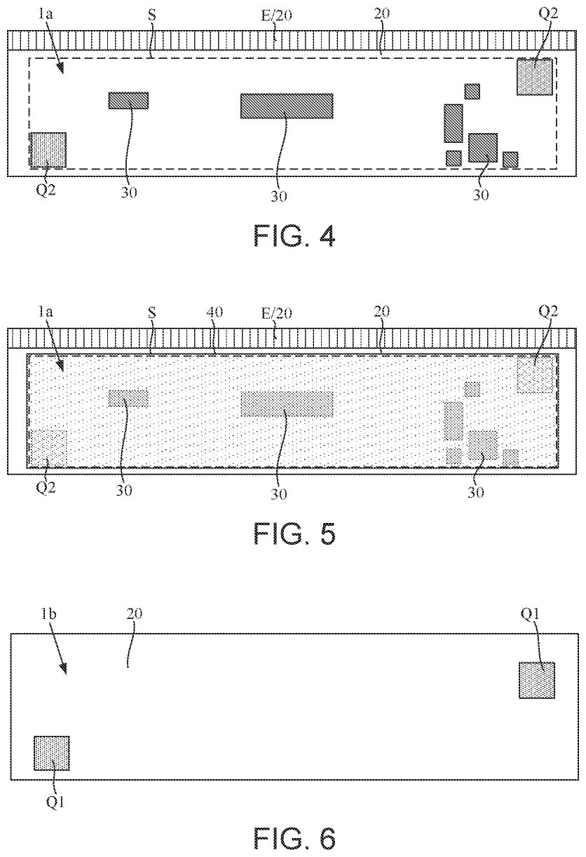

For example, as shown in FIG. 4, there may be a plurality of electronic devices 30, the plurality of electronic devices 30 are all disposed in an electronic device region S, and adjacent electronic devices 30 are arranged at intervals.

As shown in FIGS. 2, 3 and 5, the copper foil 40 covers the electronic device(s) 30.

For example, each electronic device 30 corresponds to a copper foil 40.

For example, as shown in FIG. 5, the plurality of electronic devices 30 are disposed in the electronic device region S; and the copper foil 40 covers the entire electronic device region S, thus covering the electronic devices 30.

For example, the copper foil 40 and the electronic device 30 are insulated from each other, so as to avoid the short circuit of the electronic device 30 caused by the overlapping of the copper foil 40 and pins of the electronic device 30.

For example, as shown in FIGS. 4 and 5, the circuit board 20 further includes a plurality of pins E that are configured to be bonded to and electrically connected to the FPC.

For example, as shown in FIG. 5, the copper foil 40 is arranged to bypass the pins E.

For example, the copper foil 40 may be in direct or indirect contact with the rear housing that is made of metal. Therefore, the heat of the electronic device 30 may be transmitted to the metal rear housing through the copper foil 40, so as to accelerate the heat dissipation and improve the heat dissipation performance of the display module 100.

The electronic device 30 is one of the components that generate the most heat in the display module 100. By arranging the copper foil 40 on the electronic device 30, it may be possible to accelerate the heat dissipation of the electronic device 30, and avoid that the heat generated by the electronic device 30 is accumulated in the display module 100 to cause the damage to the components of the display module 100, and in turn prolong the service life of the display module 100.

In exemplary embodiments, a thickness of the copper foil 40 is approximately in a range of 0.015 mm to 0.02 mm. For example, the thickness of the copper foil 40 may be 0.015 mm, 0.0155 mm, 0.016 mm, 0.018 mm, or 0.02 mm.

By controlling the thickness of the copper foil 40 in a range of 0.015 mm to 0.02 mm, it ensures the heat dissipation effect of the copper foil 40 on the electronic device 30 to a great extent, and it avoids that the thickness of the display module 100 is increased due to the copper foil 40, which affects the light and thin design of the display apparatus 1000.

As shown in FIGS. 2, 3 and 7, the graphite film 50 is disposed on the second surface 1b of the circuit board 20.

For example, a material of the graphite film 50 may include graphite, graphene, or a composite structure of graphite and graphene.

For example, as shown in FIG. 7, a boundary of the graphite film 50 is flush with a boundary of the circuit board 20, so that the graphite film 50 completely covers the circuit board 20, which may increase a heat dissipation area of the circuit board 20 and improve a heat dissipation efficiency of the circuit board 20.

By arranging the graphite film 50 on the second surface 1b of the circuit board 20, the graphite film 50 dissipates heat from the circuit board 20 through the second surface 1b of the circuit board 20. On the basis that the copper foil 40 dissipates heat of the circuit board 20, the graphite film 50 may further accelerate the heat dissipation efficiency of the circuit board 20, which avoids a problem of the accumulation, on the circuit board 20, of heat generated by the electronic device 30 during the process of driving the display panel 10 to emit light and display images, which causes a large amount of heat of the circuit board 20 and affects the service life of the display module 100.

In exemplary embodiments, a thickness of the graphite film 50 is approximately in a range of 0.02 mm to 0.035 mm. For example, the thickness of the graphite film 50 may be 0.02 mm, 0.025 mm, 0.03 mm, 0.0325 mm, or 0.035 mm.

By controlling the thickness of the graphite film 50 in a range of 0.02 mm to 0.035 mm, it ensures the heat dissipation effect of the graphite film 50 on the circuit board 20 to a great extent, and it avoids that the thickness of the display module 100 is increased due to the graphite film 50, which affects the light and thin design of the display apparatus 1000.

For example, as shown in FIG. 3, the display module 100 further includes a middle frame 60. After the FPC is bent toward the non-display side of the display panel 10 such that the circuit board 20 is located on the non-display side of the display panel 10, the display panel 10 and the circuit board 20 are assembled through the middle frame 60.

As shown in FIG. 3, the middle frame 60 is disposed between the display panel and the circuit board 20, and the middle frame 60 is fixedly connected to the display panel 10 and the circuit board 20.

As shown in FIG. 3, the graphite film 50 is disposed between the middle frame 60 and the circuit board 20. The graphite film 50 transmits the heat in the circuit board 20 to the middle frame 60 and finally to an outside of the display module 100, thus realizing the heat dissipation of the display module 100.

For example, the middle frame 60 may be assembled with the front frame and the rear housing, so as to form a structure for protecting and fixing the display module 100.

In some embodiments, as shown in FIGS. 2 and 3, the display module 100 further includes a first bonding layer M1. The first bonding layer M1 is disposed between the circuit board 20 and the graphite film 50.

The first bonding layer M1 is configured to fix the graphite film 50 on the circuit board 20.

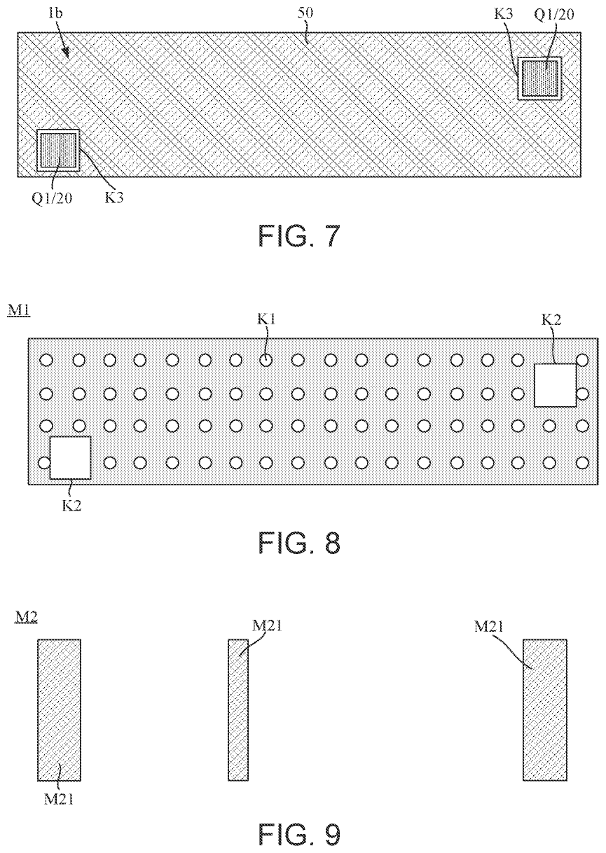

As shown in FIG. 8, the first bonding layer M1 is provided therein with a plurality of openings K1. By providing the plurality of openings K1 in the first bonding layer M1, the first bonding layer M1 is in a shape of a grid.

The inventors of the present disclosure have found that, the first bonding layer M1 and other colloid materials have poor heat dissipation capability, and coating the graphite film 50 with the first bonding layer M1 will block the heat conductive path of the graphite film 50 and reduce the heat dissipation capability of the graphite film 50, which will greatly affects the heat dissipation effect of the display module 100.

Since the first bonding layer M1 is in a shape of a grid, it may be possible to ensure the bonding strength of the first bonding layer M1, prevent the graphite film 50 from falling off from the circuit board 20, and reduce an area occupied by the first bonding layer M1 on the graphite film 50 through the openings K1. Therefore, the effect of the heat transmitted from the circuit board 20 to the graphite film 50 is improved, and the effective heat dissipation of the circuit board 20 is realized, which avoids that the service life of the components carried by the circuit board 20 and the display panel 10 is shortened due to the excessive heat of the circuit board 20.

For example, a thickness of the first bonding layer M1 is approximately in a range of 0.001 mm to 0.003 mm. For example, the thickness of the first bonding layer M1 may be 0.001 mm, 0.00125 mm, 0.0015 mm, 0.002 mm, 0.0028 mm, or 0.003 mm.

By controlling the thickness of the first bonding layer M1 in a range of 0.001 mm to 0.003 mm, the ultra-thin design of the first bonding layer M1 may be realized. Therefore, it may be possible to avoid increasing the thickness of the display module 100 and realize the light and thin design of the display apparatus 1000; in addition, it is ensured that the first bonding layer M1 adheres and fixes the graphite film 50 to the circuit board 20, and the ultra-thin first bonding layer M1 may reduce its blocking effect on the heat conductivity of the circuit board 20 and the graphite film 50. As a result, the heat dissipation capability of the graphite film 50 is ensured, the heat dissipation effect of the circuit board 20 is improved, the heat of the circuit board 20 is reduced, and the service life of the circuit board 20, the display panel 10 and the display apparatus 1000 is prolonged.

In exemplary embodiments, the above-mentioned openings K1 have a shape of a circle, an ellipse, or a polygon, which is not limited in the present disclosure.

In exemplary embodiments, a diameter of at least one opening K1 in the first bonding layer M1 is approximately in a range of 0.3 mm to 0.7 mm. For example, the diameter of the at least one opening K1 in the first bonding layer M1 may be 0.3 mm, 0.35 mm, 0.425 mm, 0.5 mm, 0.68 mm, or 0.7 mm.

In exemplary embodiments, among the plurality of openings K1, a distance between two adjacent openings K1 is approximately in a range of 8 mm to 12 mm. For example, the distance between the two adjacent openings K1 is 8 mm, 8.5 mm, 9.8 mm, 10.25 mm, 11.78 mm, or 12 mm.

By setting the shape and size of the openings K1 and the distance between adjacent openings K1, the first bonding layer M1 may satisfy the bonding strength, the blocking effect of the first bonding layer M1 on the heat transmission from the circuit board 20 to the graphite film 50 is reduced, the heat dissipation effect of the graphite film 50 on the circuit board 20 is improved, and the heat of the circuit board 20 is reduced.

In some embodiments, as shown in FIG. 6, the circuit board 20 further includes first exposed copper regions Q1 located on the second surface 1b.

The circuit board 20 is prone to breakdown due to electrostatic discharge, which affects the service life of the display module 100.

By setting the first exposed copper regions Q1 and grounding the first exposed copper regions Q1, the static electricity may be transmitted to the outside of the display apparatus 1000, so that the accumulated static electricity on the circuit board 20 may be dissipated, which avoids the damage to the circuit board 20 and the components carried by the circuit board 20 due to electrostatic breakdown, and improves the service life of the display module 100.

The first bonding layer M1 is arranged to bypass the first exposed copper regions Q1.

For example, as shown in FIG. 8, portions of the first bonding layer M1 corresponding to the first exposed copper regions Q1 are provided with first openings K2, so that the first bonding layer M1 avoids the first exposed copper regions Q1.

Since the first bonding layer M1 is arranged to bypass the first exposed copper regions Q1, it is avoided that the first bonding layer M1 covers the first exposed copper regions Q1 to interrupt the transmission path of static electricity, which facilitates the grounding of the first exposed copper regions Q1. Therefore, the static electricity in the circuit board 20 is transmitted to the outside to realize the elimination of static electricity, so as to prolong the service life of the circuit board 20 and the components and improve the stability of the circuit board 20 and the display apparatus 1000.

In some embodiments, the graphite film 50 is arranged to bypass the first exposed copper regions Q1.

For example, as shown in FIG. 7, the graphite film 50 is provided therein with second openings K3, and the second openings K3 correspond to the first exposed copper regions Q1, so that the graphite film 50 avoids the first exposed copper regions Q1.

Since the graphite film 50 is arranged to bypass the first exposed copper regions Q1, it is avoided that the graphite film 50 covers the first exposed copper regions Q1 to interrupt the transmission path of static electricity, which facilitates the grounding of the first exposed copper regions Q1. Therefore, the static electricity in the circuit board 20 is transmitted to the outside to realize the elimination of static electricity, so as to prolong the service life of the circuit board 20 and the components and improve the stability of the circuit board 20 and the display apparatus 1000.

In some embodiments, as shown in FIGS. 2 and 3, the display module 100 further includes a second bonding layer M2.

As shown in FIG. 9, the second bonding layer M2 includes a plurality of first bonding blocks M21.

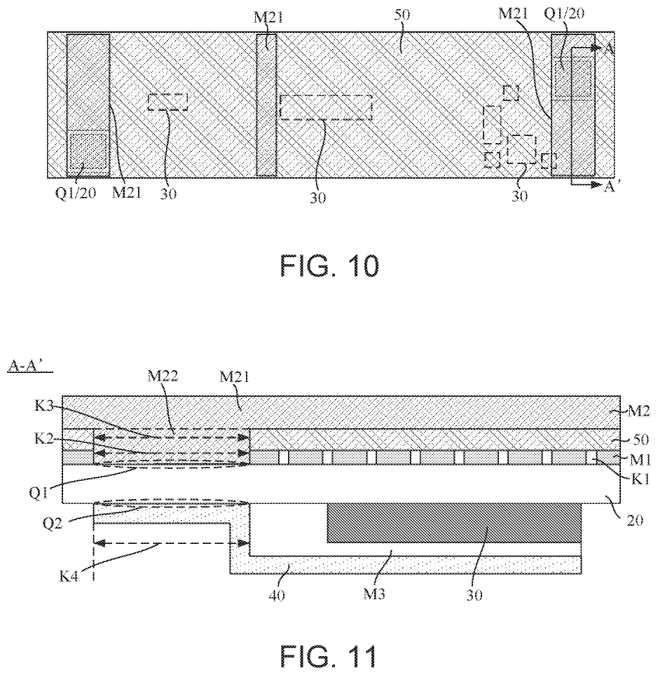

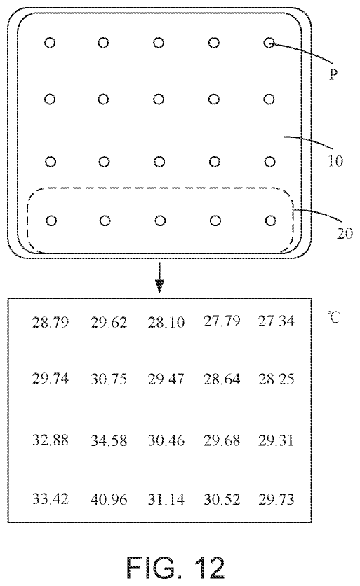

As shown in FIGS. 10 and 11, the plurality of first bonding blocks M21 are located on a side of the graphite film 50 away from the circuit board 20.

For example, as shown in FIGS. 9 and 10, the first bonding blocks M21 have a rectangular shape.

For example, as shown in FIG. 3, the second bonding layer M2 is disposed between the middle frame 60 and the circuit board 20.

The second bonding layer M2 is configured to adhere and fix the circuit board 20 on the middle frame 60, so as to realize the assembly of the display panel 10, the middle frame 60 and the circuit board 20.

The second bonding layer M2 includes the plurality of first bonding blocks M21. That is, the second bonding layer M2 is arranged in blocks. Therefore, the firmness of the bonding between the circuit board 20 and the middle frame 60 is ensured, and the second bonding layer M2 is prevented from blocking the heat dissipation of the circuit board 20. Since the second bonding layer M2 are arranged in blocks, it may be possible to reduce the contact area between the second bonding layer M2 and the graphite film 50, and in turn prevent the second bonding layer M2 from blocking the heat dissipation path from the graphite film 50 to the middle frame 60 and improve the heat dissipation effect of the graphite film 50 on the circuit board 20.

For example, a thickness of the first bonding block M1 is approximately in a range of 0.005 mm to 0.015 mm. For example, the thickness of the first bonding block may be 0.005 mm, 0.006 mm, 0.0075 mm, 0.00875 mm, 0.009 mm, 0.01 mm, 0.013 mm, 0.0145 mm, or 0.015 mm.

By controlling the thickness of the first bonding block M1 in a range of 0.005 mm to 0.015 mm, the bonding strength of the second bonding layer M2 is ensured, and the assembly firmness of the display panel 10 and the circuit board 20 is ensured.

In exemplary embodiments, as shown in FIG. 4, the display module 100 further includes electronic devices 30. The electronic devices 30 are disposed on the first surface 1a of the circuit board 20.

As shown in FIG. 10, the first bonding blocks M21 are arranged to bypass the electronic devices 30. That is, orthographic projections of the first bonding blocks M21 on the circuit board 20 and orthographic projections of the electronic devices 30 on the circuit board 20 are staggered.

For example, the first bonding blocks M21 avoid part of electronic devices 30 that generate a large amount of heat among the plurality of electronic devices 30. For example, the first bonding blocks M21 are arranged to bypass the light-emitting device driving circuit.

The electronic device 30 generates a large amount of heat. The first bonding blocks M21 are arranged to bypass the electronic device 30, especially to avoid a main heat-generating device in the electronic device 30. Therefore, it may be possible to prevent the second bonding blocks M21 from blocking the heat dissipation at a position of the main heat-generating device, ensure the heat dissipation effect of the main heat-generating device, and in turn improve the heat dissipation effect of the entire display module 100.

In exemplary embodiments, as shown in FIG. 6, the circuit board 20 further includes first exposed copper regions Q1 located on the second surface 1b.

As shown in FIG. 11, the second bonding layer M2 further includes a second bonding block M22 covering a first exposed copper region Q1, and the second bonding block M22 is conductive and in electrical contact with the first exposed copper region Q1. The second bonding layer M2 is further configured to transmit static electricity in the circuit board 20 to an outside (e.g., the middle frame 60).

For example, as shown in FIG. 3, the second bonding layer M2 is in contact with the middle frame 60.

Since the second bonding block M22 is conductive and in electrical contact with the first exposed copper region Q1, the static electricity in the circuit board 20 may be transmitted to the outside (for example, the middle frame 60) through the first exposed copper region Q1 and the second bonding block M22 in sequence, so as to realize the grounding of the first exposed copper region Q1. Therefore, the static electricity in the circuit board 20 is dissolved, and the breakdown of the circuit board 20 and the components carried by the circuit board 20 caused by the electrostatic discharge is avoided. As a result, the service life of the display module 100 is prolonged.

For example, as shown in FIG. 11, the second bonding block M22 is filled in the first opening K2 and the second opening K3. That is, the second bonding layer M2 penetrates through the first bonding layer M1 and the graphite film 50 and then is in electrical contact with the first exposed copper region Q1.

For example, as shown in FIG. 11, the second bonding block M22 is disposed on a side of the first bonding block M21 proximate to the circuit board 20.

For example, as shown in FIG. 11, the second bonding block M22 and the first bonding block M21 are of an integrated structure.

For example, a material of the second bonding block M22 includes an adhesive material and a conductive material. For example, the second bonding block M22 uses an acrylic material as a base material, and the base material is filled with a conductive material, so that the conductivity and adhesiveness of the second bonding block M22 may be realized.

For example, the first bonding blocks M21 may also be conductive. For example, the first bonding block M21, which is integrated with the second bonding block M22, is conductive.

For example, a first bonding block M21, which is not integrated with the second bonding block M22, may be made of an insulating material. For example, a first bonding block M21 staggered from the first exposed copper region Q1 may be made of an acrylic material, which is not filled with a conductive material, so as to enhance the bonding strength of the second bonding layer M2.

That is, the second bonding layer M2 may be made of a conductive material; alternatively, portions of the second bonding layer M2 corresponding to the first exposed copper regions Q1 are made of a conductive material, and a portion of the second bonding layer M2 that is staggered from and the first exposed copper regions Q1 is made of an adhesive, which may reduce the cost of the second bonding layer M2 to a certain extent. In addition, the non-conductive portion of the second bonding layer M2 does not need to be filled with a conductive material, so that the bonding strength of the second bonding layer M2 may be increased, which causes a good fixing effect between the middle frame 60 and the circuit board 20.

For example, the above-mentioned conductive material may include a metal, a composite material, conductive fibers, etc. For example, the conductive material is powders of metals such as gold, silver, copper, aluminum, zinc, nickel, etc., or is graphite and some conductive compounds.

In some embodiments, as shown in FIG. 3, the display module 100 further includes a middle frame 60. The middle frame 60 is bonded to the second bonding layer M2. In a case where the second bonding layer M2 includes the second bonding blocks M22, the middle frame 60 is electrically connected to the second bonding blocks M22.

Since the second bonding layer M1 is electrically connected to the middle frame 60, the static electricity in the circuit board 20 may be transmitted to the outside of the display apparatus 1000 through the first exposed copper regions Q1, the second bonding layer M2, and the middle frame 60, so as to achieve the grounding, effectively avoid the damage to the components in the display apparatus 1000 caused by the electrostatic discharge, and prolong the service life of the display apparatus 1000.

In some embodiments, as shown in FIGS. 2, 3 and 11, the display module 100 further includes a third bonding layer M3. The third bonding layer M3 is disposed between the electronic device 30 and the copper foil 40.

As shown in FIG. 11, the third bonding layer M3 covers the electronic device 30. That is, an orthographic projection of the electronic device 30 on the circuit board 20 is located within an orthographic projection of the third bonding layer M3 on the circuit board 20.

The third bonding layer M3 is configured to fix the copper foil 40 on the first surface 1a of the circuit board 20. In addition, since the third bonding layer M3 covers the electronic device 30, the third bonding layer M3 may also be used as an insulating layer between the copper foil 40 and the electronic device 30 to avoid the short circuit of the electronic device 30 caused by the overlapping between the copper foil 40 and the pins of the electronic device 30.

For example, a thickness of the third bonding layer M3 is approximately in a range of 0.005 mm to 0.01 mm. For example, the thickness of the third bonding layer M3 may be 0.005 mm, 0.0065 mm, 0.007 mm, 0.0087 mm, 0.00925 mm, or 0.01 mm.

Since the thickness of the third bonding layer M3 is controlled to be in a range of 0.005 mm to 0.01 mm, the bonding force of the third bonding layer M3 may be satisfied, the fixation strength between the copper foil 40 and the circuit board 20 may be ensured, the influence of the third bonding layer M3 on the heat dissipation capability of the copper foil 40 is reduced, and the heat dissipation effect of the display module 100 is improved.

In some embodiments, as shown in FIGS. 4 and 11, the circuit board 20 further includes second exposed copper regions Q2 on the first surface 1a, and the third bonding layer M3 is arranged to bypass the second exposed copper regions Q2.

The first surface 1a of the circuit board 20 is provided with component(s) (e.g., the electronic device(s) 30), and when the electrostatic discharge exists, the breakdown of the circuit board 20 and the components will also occur. By setting the second exposed copper regions Q2, it may be possible to dissipate the static electricity on the first surface 1a of the circuit board 20, avoid the breakdown risk of the components, and prolong the service life of the components, the circuit board 20 and the display module 100.

In some embodiments, as shown in FIG. 11, the third bonding layer M3 includes through holes K4 for bypassing the second exposed copper regions Q2, and the copper foil 40 is in electrical contact with the second exposed copper regions Q2 through the through holes K4.

The copper foil 40 is made of a conductive material. By arranging the copper foil 40 in electrical contact with the second exposed copper regions Q2, the static electricity in the circuit board 20 may be transmitted to the outside of the display module 100 through the second exposed copper regions Q2 and the copper foil 40 in sequence, so as to achieve the electrostatic grounding of the circuit board 20, realize electrostatic elimination, avoid the damage to the components due to electrostatic discharge, and prolong the service life of the display module 100.

In addition, the static electricity in the circuit board 20 is transmitted to the copper foil 40 through the second exposed copper regions Q2, which increases the area for static electricity elimination and improves the effect of static electricity elimination.

By providing the copper foil 40 and arranging the copper foil 40 to be in electrical contact with the second exposed copper regions Q2, the copper foil 40 has heat dissipation capability, anti-electrostatic discharge (ESD) capability and anti-electromagnetic interference (EMI) capability for the electronic device 30, so that the multi-function of the copper foil 40 realized, and the copper foil 40 is utilized to the greatest extent.

For example, a side of the copper foil 40 away from the circuit board 20 is further in direct or indirect electrical contact with the metal rear housing. For example, a conductive foam is provided between the copper foil 40 and the metal rear housing, and the copper foil 40 and the metal rear housing are electrically connected to each other through the conductive foam.

Since the side of the copper foil 40 away from the circuit board 20 is in direct or indirect electrical contact with the metal rear housing, the static electricity in the circuit board 20 is transmitted to the outside of the display apparatus 1000 sequentially through the second exposed copper regions Q2, the copper foil 40 and the rear housing, so as to realize the elimination of static electricity in the circuit board 20.

In some embodiments, the display module 100 includes a first bonding layer M1 disposed between the circuit board 20 and the graphite film 50, a second bonding layer M2 disposed on a side of the graphite film 50 away from the circuit board 20, and a third bonding layer M3 disposed between the electronic device 30 and the copper foil 40. A material of at least one of the first bonding layer M1, the second bonding layer M2, and the third bonding layer M3 may include an acrylic material.

For example, when the second bonding layer M2 includes the first bonding blocks M21, the material of the first bonding blocks M21 includes an acrylic material.

For example, when the second bonding layer M2 includes the second bonding blocks M22, the material of the second bonding blocks M22 includes an acrylic material.

For example, the material of the second bonding blocks M22 further includes a conductive material. The conductive material is, for example, gold, silver, copper, aluminum, zinc, nickel and other metal powders, or may be graphite and some conductive compounds.

Based on the above embodiments, the heat dissipation of the display apparatus 1000 provided in the embodiments of the present disclosure is greatly improved.

A temperature detection is performed on the display apparatus 1000 provided in the embodiments of the present disclosure, and the detection conditions are as follows. Under a room temperature of 23.51° C., a thermocouple testing instrument of the model HIOKI LR8501 is used for testing, and temperatures corresponding to test points P and the test points P are shown in FIG. 12.

According to the detection results in FIG. 12, it can be known that the surface temperature of the display apparatus 1000 provided in the embodiments of the present disclosure may be controlled within 45° C. at the highest. Compared with the display apparatus with the temperature of 50° C. or even above 80° C. in the related art, the display apparatus 1000 provided in the embodiments of the present disclosure may not only ensure a small change in the structure and thickness of the whole machine, but also have a low manufacturing cost, and efficient heat conduction and heat dissipation capability, so as to effectively prolong the service life of the display apparatus 1000.

The foregoing descriptions are merely specific implementation manners of the present disclosure, but the protection scope of the present disclosure is not limited thereto. Changes or replacements that any person skilled in the art could conceive of within the technical scope of the present disclosure shall all be included in the protection scope of the present disclosure. Therefore, the protection scope of the present disclosure shall be subject to the protection scope of the claims.

1. A display module, comprising:
a display panel;
a circuit board electrically connected to the display panel, the circuit board including a first surface and a second surface that are opposite to each other;
an electronic device disposed on the first surface of the circuit board;
a copper foil covering the electronic device; and
a graphite film disposed on the second surface of the circuit board.

2. The display module according to claim 1, further comprising:
a first bonding layer disposed between the circuit board and the graphite film, the first bonding layer being provided therein with a plurality of openings.

3. The display module according to claim 2, wherein the circuit board further includes first exposed copper regions located on the second surface, and the first bonding layer is arranged to bypass the first exposed copper regions.

4. The display module according to claim 3, wherein the graphite film is arranged to bypass the first exposed copper regions.

5. The display module according to claim 2, wherein a thickness of the first bonding layer is approximately in a range of 0.001 mm to 0.003 mm.

6. The display module according to claim 2, wherein a diameter of at least one of the plurality of openings in the first bonding layer is approximately in a range of 0.3 mm to 0.7 mm.

7. The display module according to claim 2, wherein a distance between two adjacent openings among the plurality of openings is approximately in a range of 8 mm to 12 mm.

8. The display module according to claim 1, further comprising:
a second bonding layer including a plurality of first bonding blocks, wherein the plurality of first bonding blocks are located on a side of the graphite film away from the circuit board.

9. The display module according to claim 8, wherein the plurality of first bonding blocks are arranged to bypass the electronic device.

10. The display module according to claim 8, wherein the circuit board further includes first exposed copper regions located on the second surface;
the second bonding layer further includes a second bonding block covering a first exposed copper region of the first exposed copper regions, and the second bonding block is conductive and in electrical contact with the first exposed copper region.

11. The display module according to claim 8, further comprising:
a middle frame bonded to the second bonding layer;
wherein the second bonding layer includes a second bonding block, and the middle frame is electrically connected to the second bonding block.

12. The display module according to claim 8, wherein a thickness of the first bonding blocks is approximately in a range of 0.005 mm to 0.015 mm.

13. The display module according to claim 1, further comprising:
a third bonding layer disposed between the electronic device and the copper foil, the third bonding layer covering the electronic device.

14. The display module according to claim 13, wherein the circuit board further includes second exposed copper regions located on the first surface, and the third bonding layer is arranged to bypass the second exposed copper regions.

15. The display module according to claim 14, wherein the third bonding layer includes through holes for bypassing the second exposed copper regions, and the copper foil is in electrical contact with the second exposed copper regions through the through holes.

16. The display module according to claim 13, wherein a thickness of the third bonding layer is approximately in a range of 0.005 mm to 0.01 mm.

17. The display module according to claim 1, further comprising:
a first bonding layer disposed between the circuit board and the graphite film;
a second bonding layer disposed on a side of the graphite film away from the circuit board; and
a third bonding layer disposed between the electronic device and the copper foil;
wherein a material of at least one of the first bonding layer, the second bonding layer and the third bonding layer includes an acrylic material.

18. The display module according to claim 1, wherein a thickness of the graphite film is approximately in a range of 0.02 mm to 0.035 mm.

19. The display module according to claim 1, wherein a thickness of the copper foil is approximately in a range of 0.015 mm to 0.02 mm.

20. A display apparatus, comprising the display module according to claim 1.
